(19) United States
(12) Patent Application Publication
(10) Pub. No.: US 2008/0166664 A1
(43) Pub. Date: Jul. 10, 2008

(54) METHOD FOR FORMING A RESIST PATTERN USING A SHRINKING TECHNOLOGY

(75) Inventor: Yoichi NOMURA, Tokyo (JP)

Correspondence Address: YOUNG & THOMPSON, 209 Madison Street, Suite 500, ALEXANDRIA, VA, 22314, US

(73) Assignee: ELPIDA MEMORY, INC., TOKYO (JP)

(21) Appl. No.: 11/971,922

(22) Filed: Jan. 10, 2008

(30) Foreign Application Priority Data
Jan. 10, 2007 (JP) 2007-002021

(51) Int. Cl. G03F 7/26

(52) U.S. Cl. 430/311; 430/322

(57) ABSTRACT

A method of forming a resist pattern includes the steps of: forming a photoresist pattern on a wafer by exposure and development of a photoresist film; treating the surface of the photoresist pattern by using a resist solvent; and thermally flowing the treated photoresist pattern for shrinkage. An isotropic shrinkage amount is obtained for the hole pattern including a dense portion and an isolated portion of the holes.

This application is based upon and claims the benefit of priority from Japanese patent application No. 2007-002021, the disclosure of which is incorporated herein in its entirety by reference.

### BACKGROUND OF THE INVENTION

1. Field of the Invention

The present invention relates to a method of forming a resist pattern on a wafer and a method of manufacturing a semiconductor device, and more particularly to a method of forming a resist pattern by using a shrinkage technology including a thermal flow and a method of manufacturing a semiconductor device using such a resist pattern forming method

2. Description of the Related Art

Higher integration of semiconductor devices has progressively been achieved from year to year, and a photolithographic technique is one of the key technologies which lead the higher integration. The photolithographic technique is used to form fine circuit patterns that configure device elements on a wafer. Conventionally a smaller pattern formed by the photolithography has been achieved by reducing the wavelength of the light source. However, there is a limit to further reduce the wavelength of the light source. In such circumstances, there has been proposed a technology that employs a shrinkage technology, and adopted to reduce the dimensions of the resist pattern once formed by the photolithography, to thereby form a fine resist pattern having a dimension smaller than the wavelength of the light source. Examples of known shrinkage technology include a method of causing a thermal flow on the resist pattern by using a high-temperature heat treatment and another method of using a mixing-generation resist film in addition to the resist pattern formed by the photolithography. The shrinkage technology using thermal flow is described, for example, in Patent Publications JP-2004-95803-A1 and JP-2005-150222-A1.

An example of the conventional shrinkage process using the thermal flow will now be described. First, a resist film is formed by coating onto the surface of a thin film to be patterned, followed by exposing the same to exposure light and subsequent development of the resist film. In this step, KrF resist GKR 5315D7 (480 nm), for example, is used for the resist film, and KrF scanning exposure apparatus, ES6 from Canon Inc., is used for exposure of the resist film. Further, Lithius from Tokyo Electron Ltd. is used as a coating/developing apparatus.

Generally, the layout of a hole pattern includes a dense portion and an isolated portion. The dense portion may include a plurality of holes each having a diameter of, for example, 0.13 μm, which are arranged in an array at a pitch that corresponds to the hole diameter in proportion of 1:2 therebetween. The isolated portion may include a plurality of holes having a diameter of, for example, 0.18 μm, and are arranged at random or at a smaller density.

FIG. 4 shows an example of a process for treating a semiconductor wafer, wherein the semiconductor wafer 20 mounting thereon the above resist pattern is introduced into a thermal flow apparatus 10 having a hot plate 11 therein, and then the pattern size reduction is carried out using the thermal flow technique. The amount of shrinkage of the pattern caused by the thermal flow process is about 50 to 80 nm in the example under the conditions as described above. The baking temperature during the thermal flow process is at around 140° C., which is a glass transition point (Tg) of KrF resist GKR5315D7. In the dense portion of the semiconductor wafer 20, where the holes are arranged in an array, the shrinkage of the pattern occurs uniformly. On the other hand, in the isolated portion where the holes are randomly arranged, a defect is observed that the pattern shrinkage did not uniformly occur, and the resultant pattern was deformed. This phenomenon was assured in an experiment conducted by the inventor as detailed below.

A photoresist 21 having therein holes 22, which are arranged in a single row as shown in FIG. 5 was allowed to shrink by way of the thermal flow. Holes 24 of the post-shrink pattern were deformed as shown in FIG. 6. This deformation resulted from a smaller amount of shrinkage occurring along the alignment direction of the pattern and a larger amount of shrinkage occurring in the direction perpendicular to the alignment direction of the pattern.

In the post-shrink pattern shown in FIG. 6, the presence of a resist insoluble layer 25 formed on the surface of the photoresist 21, as shown in FIG. 7, was observed during the development, and considered as the cause of the deformation of the pattern. The resist insoluble layer 25 on the surface of the photoresist 21 is formed by azo-coupling reaction of the resin through the medium of tetramethylammonium hydroxide (TMAH) contained in the developer. The resist insoluble layer 25 is higher in atomic density in a given volume of carbon as compared with the resist resin, causing a flow impediment with respect to the thermal flow.

The amount of the resist insoluble layer 25 thus formed is larger in the case of a higher pattern density, and is less in the case of a lower pattern density. For this reason, a higher pattern density scarcely involves less degree of thermal flow; and a lower pattern density has a tendency of involving a higher degree of thermal flow. The deformation caused by this phenomenon is especially prominent when a difference in the degree of density is large between two directions in the two-dimensional arrangement. Therefore, the pattern arranged in a single row as shown in FIG. 5 especially involves a large deformation. Thus, in order to employ the shrinkage processing, there is a significant restriction on the pattern layout, such as including usage of a plurality of reticle patterns for a single target film.

### SUMMARY OF THE INVENTION

It is an object of the present invention to provide a pattern forming method which facilitates the control of the amount of pattern shrinkage in a shrinkage process using the thermal flow.

The present invention provides a method including: forming a photoresist pattern on a wafer by exposure and development of a photoresist film; treating a surface of the photoresist pattern by using a resin solvent; and thermally flowing the treated photoresist pattern for shrinkage thereof.

The above and other objects, features and advantages of the present invention will be more apparent from the following description, referring to the accompanying drawings.

### BRIEF DESCRIPTION OF THE DRAWINGS

FIG. 1 is a sectional view of a thermal flow apparatus, illustrating a pattern forming process according to an embodiment of the present invention;

FIG. 2 is a top plan view exemplifying the pattern of the photoresist mask which is subjected to the thermal flow in the thermal flow apparatus illustrated in FIG. 1;

FIG. 3 is a top plan view of the photoresist mask illustrated in FIG. 2 after being subjected to the thermal flow;

FIG. 4 is a sectional view of a conventional thermal flow apparatus, illustrating a pattern forming process;

FIG. 5 is a top plan view exemplifying the pattern of the photoresist mask which is subjected to the thermal flow in the thermal flow apparatus illustrated in FIG. 4;

FIG. 6 is a top plan view of the photoresist mask illustrated in FIG. 5 after being subjected to the thermal flow; and

FIG. 7 is a sectional view of the photoresist mask illustrated in FIG. 6.

### DETAILED DESCRIPTION OF THE PREFERRED EMBODIMENT

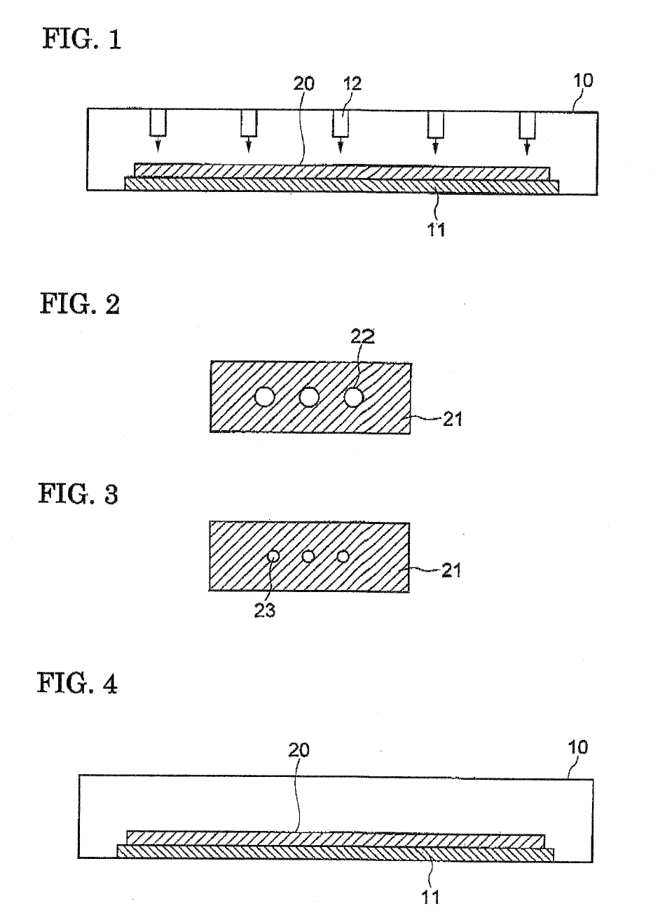

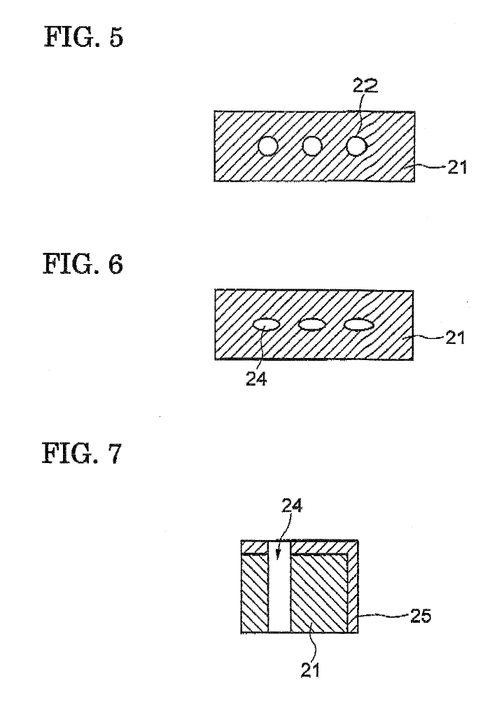

Hereinafter, an embodiment of the present invention will be described with reference to the accompanying drawings. FIG. 1 is a sectional view of a thermal flow apparatus that implements a pattern forming process according to the embodiment, illustrating a semiconductor wafer received in the apparatus. In the present embodiment, a photoresist pattern is first formed on the semiconductor wafer using a known photolithographic technique. GKR 5315D7 (480 nm), for example, is used as the resist material, and KrF scanning exposure apparatus ES6 from Canon Inc., for example, is used as the exposure system. Further, Lithius from Tokyo Electron Ltd., for example, is used as the coating/developing apparatus. In the present embodiment, as shown in FIG. 1, the pattern forming process is carried out by receiving the semiconductor wafer 20 having thereon a photoresist pattern in a thermal flow apparatus 10, and allowing the resist pattern to thermally flow by means of a hot plate 11 provided in the apparatus 10 and shrink after the thermal flow.

For achieving the thermal flow process, the semiconductor wafer 20 is first mounted on the hot plate 11, as shown in FIG. 1, and then steam of a resist solvent is sprayed onto the semiconductor wafer 20 from the tips of nozzles 12 provided on the top of the thermal flow apparatus 10. The steam of the resist solvent is supplied until the resist pattern is swollen by the resist solvent. As the resist solvent, propyleneglycol monoethylether acetate (hereinafter abbreviated as “PGMEA”) is used. In order to turn the resist solvent into steam, the resist solvent is heated up to a temperature equal to or higher than its boiling point. Since the boiling point of the PGMEA is 146° C., the reservoir for the solvent is heated up to 146° C. or higher. The steam resulted from the heating is introduced into the thermal flow apparatus 10. Consequently, the resist pattern is swollen with the steam of the solvent.

The swelling of the resist pattern by using the steam of the solvent lowers the molecular density of the resist, allowing the fluidity of the resist to be improved by heat. In this state, the thermal flow process is conducted on the resist pattern. As a result, the holes 22 of the photoresist 21, which are densely aligned in a single row, for example, as shown in FIG. 2, are modified to assume the shape of holes 23 shown in FIG. 3, each of which is shrunk substantially isotropicly in the hole diameter. That is, it is possible to prevent the amount of shrinkage from depending on the degree of the density in the pattern layout, thereby improving the controllability of the shrinkage mount. Therefore, the post-shrink dimensions of the pattern having a single row can be improved, with the result that the restriction on the pattern layout on the wafer can be reduced.

In the above embodiment, the resist solvent is turned into steam to spray the onto the resist pattern, as an example. Instead, it is also possible to use a liquid resist solvent. In this case, for example, the resist solvent is dropped in droplets from a spin-coating cup onto the semiconductor wafer having thereon the resist pattern. The resist insoluble layer is generally formed on the surface of the thus formed resist pattern, as described before. The resist insoluble layer formed on the patterned resist pattern is swollen by means of the liquid resist solvent. The resist solvent is dropped while the semiconductor wafer is revolved at a high speed. The time length needed for the dropping of the resist solvent is around 1 to 2 seconds. The number of revolutions of the semiconductor wafer per minutes is in the range of, for example, 100 to 500 (rpm). This spin coating allows the resisy solvent to permeate into the resist insoluble layer.

The resist pattern is swollen after the solvent permeates into the resim insoluble layer, whereby the thermal fluidity of the resist pattern during the heating is improved. Subsequently, the resist pattern is baked at a desired temperature on the hot plate provided within the thermal flow apparatus to perform the thermal flow. Since the thermal flow is carried out in a state where the resist insoluble layer is swollen, an isotropic pattern shrinkage can be attained. In other words, the dependence of the amount of shrinkage on the degree of density of the pattern layout can be suppressed, providing improvement in the controllability of the post-shrink dimensions. As a result, even if the patterns are aligned in a single row, an isotropic pattern shrinkage can be attained, and the restriction on the pattern layout can be reduced.

In the above embodiment, a KrF resist that uses a PHS-based resin is exemplified. Instead, a novolac-based i-line resist that is feasible for the thermal flow can also be used. Examples of the other resist solvents consists essentially of 2-heptanone, propyleneglycol monoethylether (PGME), ethyl lactate, or the like.

In the pattern forming process of the above embodiment, the resist insoluble layer formed on the surface of the photoresist is swollen by a process using the resist solvent, after the resist pattern is formed on the photoresist film and before the thermal flow is conducted. This increases the fluidity of the resist pattern during the process of heating for the thermal flow. Thus, the amount of shrinkage of the resist in the thermal flow does not depend on the degree of density of the pattern layout, which improves the accuracy of controlling for the amount of shrinkage.

While the invention has been particularly shown and described with reference to exemplary embodiment and modifications thereof, the invention is not limited to these embodiment and modifications. It will be understood by those of ordinary skill in the art that various changes in form and details may be made therein without departing from the spirit and scope of the present invention as defined in the claims.

What is claimed is:

1. A method comprising:
forming a photoresist pattern on a wafer by exposure and development of a photoresist film;
treating a surface of said photoresist pattern by using a resist solvent; and
thermally flowing said treated photoresist pattern for shrinkage thereof.

2. The method according to claim 1, wherein said treating using said resist solvent swells a resist insoluble layer formed on said surface of said photoresist pattern.

3. The method according to claim 2, wherein said treating using said resist solvent sprays a steam resist solvent onto said photoresist pattern

4. The method according to claim 2, wherein said treating using said resist solvent drops a liquid resist solvent onto a surface of said photoresist pattern.

5. The method according to claim 4, wherein said treating using said resist solvent revolves said photoresist pattern, on which said liquid resist solvent is dropped, at a predetermined rotational speed or higher.

6. The method according to claim 1 wherein said resist solvent consists essentially of propyleneglycol monoethylether acetate.

7. The method according to claim 1, wherein said resist solvent consists essentially of propyleneglycol monoethylether.

8. The method according to claim 1, wherein said resist solvent consists essentially of ethyl lactate.

9. A method for manufacturing a semiconductor device, comprising the method according to claim 1.
